(19) United States
(12) Patent Application Publication
(10) Pub. No.: US 2006/0019493 A1
(43) Pub. Date: Jan. 26, 2006

(54) Methods of metallization for microelectronic devices utilizing metal oxide

(76) Inventor: Wei Min Li, Espoo (FI)

Correspondence Address: KNOBBE MARTENS OLSON & BEAR LLP, 2040 MAIN STREET, FOURTEENTH FLOOR, IRVINE, CA, 92614, US

(21) Appl. No.: 11/179,791

(22) Filed: Jul. 11, 2005

Related U.S. Application Data
(60) Provisional application No. 60/588,844, filed on Jul. 15, 2004.

(51) Int. Cl. H01L 21/44; H01L 21/461; H01L 21/26

(52) U.S. Cl. 438/680; 438/706; 438/798

(57) ABSTRACT

A metal oxide is deposited on a substrate in a semiconductor fabrication metallization process is patterned and subsequently reduced to a more conductive form, such as elemental metal. The metal oxide is reduced by exposure to at least one reducing agent or current that is capable of removing oxygen from the metal oxide. Copper oxide, for example, can be dry etched for patterning prior to reduction to copper metal, and the patterned copper used as an ECD seed layer.

### REFERENCE TO RELATED APPLICATON

The present non-provisional application claims the priority benefit of U.S. provisional application No. 60/588,844, filed Jul. 15, 2004, which is incorporated herein by reference. The present application is also related to U.S. application Ser. No. 10/300,168, filed Nov. 19, 2002, now U.S. Pat. No. 6,887,795, and U.S. application Ser. No. 09/975,466, filed Oct. 9, 2001, now U.S. Pat. No. 6,878,628.

### FIELD OF THE INVENTION

The invention relates generally to methods of metallization in which metal oxide is deposited, etched and subsequently reduced to elemental metal in semiconductor processing.

### BACKGROUND OF THE INVENTION

When fabricating integrated circuits, layers of insulating, conducting and semiconducting materials are deposited and patterned to produce desired structures. A process of fabricating a semiconductor integrated circuit is roughly divided into the process of forming devices on a substrate and the process of electrically connecting the devices. The latter is called an interconnection process or metallization, and is a key for improving yield rate and reliability in the fabrication of semiconductor devices as the devices become more highly integrated.

“Back end” or metallization processes include contact formation and metal line formation. Contact formation vertically connects conductive layers through an insulating layer. Conventionally, contact vias or openings are formed in the insulating layer, which typically comprises a form of oxide such as borophosphosilicate glass (BPSG) or oxides formed from tetraethylorthosilicate (TEOS) precursors. The vias are then filled with conductive material, thereby interconnecting electrical devices and wiring above and below the insulating layers. The layers interconnected by vertical contacts typically include horizontal metal lines running across the integrated circuit. Such lines are conventionally formed by depositing a metal layer over the insulating layer, masking the metal layer in a desired wiring pattern, and etching away metal between the desired wires or conductive lines.

Due to its high conductivity, copper metallization is currently the most preferred method in the fabrication of high-speed microelectronic devices. However, dry etch processes for copper are not available, such that conventional deposition and etch is not commercially employed. Instead, because chemical mechanical polishing (CMP) is available for copper, damascene or in-laid processing of copper metal in trenches and vias has been the mainstream approach for copper wiring. Damascene processing involves forming trenches in the pattern of the desired lines, filling the trenches with a metal or other conductive material, and then polishing the metal back to the insulating layer. Wires are thus left within the trenches, isolated from one another in the desired pattern. The polishing process thus avoids more difficult photolithographic mask and etching processes of conventional metal line definition, particularly dry etching for copper metallization, which has not been satisfactorily developed.

In an extension of damascene processing, a process known as dual damascene involves forming two insulating layers, typically separated by an etch stop or hard mask material, and forming trenches in the upper insulating layer, as described above for damascene processing. Contact vias are etched through the floor of the trenches and the lower insulating layer to expose lower conductive elements where contacts are desired. As one of skill in the art will recognize, a number of processes are available for forming dual damascene structures. For example, trenches may be etched through the upper insulating layer, after which a further mask is employed to etch the contact vias or the etch continues through a previously defined, buried hard mask. In an alternative embodiment, contact vias are first etched through the upper and lower insulating layers, after which the via in the upper insulating layer is widened to form a trench.

Protective barriers are often formed between via or trench walls and metals in a substrate assembly, to aid in confining deposited material within the via or trench walls. These lined vias or trenches are then filled with metal by any of a variety of processes, including chemical vapor deposition (CVD), atomic layer deposition (ALD), physical vapor deposition (PVD), and electroplating.

Typically, a blanket copper seed layer is deposited by CVD, PVD, or ALD across the entire substrate. An electrically conductive seed layer is typically needed for electroplating processes. In one process, described in U.S. Pat. No. 6,482,740, the disclosure of which is incorporated herein by reference, a seed layer is first formed as a copper oxide layer by ALD. The copper oxide is at least partially converted into copper metal in a separate process step to increase the conductivity of the deposited oxide thin film. The conversion step can be done with a reducing agent, typically in gaseous phase, capable of forming a stronger bond to oxygen than the copper to be reduced. The seed layer serves to provide current across the substrate for uniform ECD, but the seed layer can also act as a nucleation layer for a CVD process.

In ALD, the sequential introduction of precursor species (e.g., a first precursor and a second precursor) to a substrate, which is located within a reaction space, is generally employed. Typically, one of the initial steps of ALD is the adsorption of the first precursor on the active sites of the substrate. Conditions are such that no more than a monolayer forms so that the process is self-terminating or saturative. For example, the first precursor can include ligands that remain on the adsorbed species, which prevents further adsorption. Accordingly, deposition temperatures are maintained above the precursor condensation temperatures and below the precursor thermal decomposition temperatures. This initial step of adsorption is typically followed by a first removal (e.g., purging) stage, where the excess first precursor and possible reaction byproducts are removed from the reaction chamber. The second precursor is then introduced into the reaction chamber. The first and second precursors typically tend to react with each other. As such, the adsorbed monolayer of the first precursor reacts instantly with the introduced second precursor, thereby producing the desired thin film. This reaction terminates once the adsorbed first precursor has been consumed. The excess of second precursor and possible reaction byproducts are then removed, e.g., by a second purge stage. The cycle can be repeated to grow the film to be a desired thickness. Cycles can also be more complex. For example, the cycles can include three or more reactant pulses separated by purge and/or evacuation steps.

In ALD, films grow with a constant growth rate. Each deposition cycle produces one molecular layer of the deposited material on the substrate surface. It is well known that metal oxide thin films produced by ALD are uniform, have excellent adhesion, and thus are firmly bonded to the substrate surface.

ALD also provides excellent step coverage, even on large areas, and a dense and pinhole-free structure. Therefore, it is of great interest to apply ALD to the deposition of metallization layers of advanced integrated circuits, where the continuously increasing packing density and aspect ratio set higher and higher demands upon the metallization layers.

In one example of the formation of a copper seed layer by ALD, copper is directly deposited from alternate pulses of bis (1,1,1,5,5,5-hexafluoroacetylacetonato)copper(ii)hydrate and either methanol, ethanol, or formalin, i.e. a water solution of formaldehyde. The total pulsing cycle is typically about 64 seconds. A typical growth rate of a thin film made by ALD from metal β-diketonates is 0.03 nm/cycle due to the steric hindrance of the source chemical molecules. Thus, the deposition time for a 10 nm copper seed layer would be over five hours, which is uneconomical for wafer processing. Practically speaking, commercially acceptable throughput of a wafer reactor is about 10-12 wafers/hour or greater.

For electrochemical deposition, (ECD), the substrate having an electrically conductive seed layer, however produced, is typically placed in a bath containing a metal compound solution and connected to an external DC power supply. A current passes through the substrate surface into the solution and metal is deposited on the substrate. The seed layer has high conductivity and it acts as a conduction and nucleation layer for the electroplating process. The seed layer carries current from the edge of the wafer to the center of the wafer and from the top surface of the wafer into the bottom of vias and trenches. A uniform and continuous seed layer across the substrate is desirable to form uniform electroplated copper. Electrical contact is made to the seed layer. The quantity of the deposited metal is directly proportional to the local current density on the substrate.

Copper metallization is often a preferred method of fabrication of high-speed microelectronic devices, and damascene of copper metal in trenches and vias is a commonly used method for copper wiring. However, one of the difficulties in copper metallization is the etching of metallic copper and cleaning of copper contaminants after the etching process. The difficulties in copper etching and cleaning hinder its uses in, for example, metal-electrode applications. Although chemical mechanical planarization (CMP) is typically used to etch copper in damascene copper metallization, more effective etching and cleaning methods are needed for copper metallization.

### SUMMARY OF THE INVENTION

According to one aspect of the present invention, a method of producing a conductive thin film is provided, comprising depositing metal oxide on a substrate by atomic layer deposition, patterning the metal oxide, and at least partially reducing the metal oxide after patterning. The atomic layer deposition comprises contacting the substrate with alternating vapor pulses of at least one first source chemical comprising a compound capable of adsorbing no more than a monolayer of metal species on the substrate and at least one second source chemical comprising a compound capable of oxidizing the metal species on the substrate into the metal oxide. The reduction may be done with organic or inorganic reducing agents. According to another aspect of the invention, electric current can be used to reduce the metal oxide.

According to another aspect of the invention, a method of producing a transistor gate is provided, comprising depositing an insulating layer on a substrate and depositing a first diffusion barrier layer on the insulating layer. Metal oxide is then deposited on the first diffusion barrier layer by atomic layer deposition and the metal oxide is patterned. After patterning, the metal oxide is dry etched. After dry etching, the metal oxide is at least partially reduced. A second diffusion barrier layer is then deposited on the substrate after at least partially reducing the metal oxide. According to a preferred embodiment, the atomic layer deposition comprises contacting the substrate with alternating vapor phase pulses of a first source chemical comprising a compound capable of adsorbing no more than a monolayer of metal species on the substrate and a second source chemical comprising a compound capable of oxidizing the metal species on the substrate into the metal oxide and removing an excess of the second source chemical.

According to yet another aspect of the invention, a method of producing a capacitor is provided, comprising providing a silicon substrate having a trench capacitor and depositing a first diffusion barrier, a metal wordline, and a second diffusion barrier to encapsulate the metal wordline between the first and second diffusion barriers. An insulator is then formed on the substrate and patterned. Contact plug vias are etched in the insulator and a third diffusion barrier is deposited on the insulator. Copper oxide is deposited on the third diffusion barrier by atomic layer deposition and patterned. After patterning, the copper oxide is dry etched and then at least partially reduced to form copper metal. A fourth diffusion barrier is then deposited on the substrate and patterned to encapsulate the elemental copper within the third and fourth diffusion barriers.

### BRIEF DESCRIPTION OF THE DRAWINGS

These and other aspects of the invention will be readily apparent to the skilled artisan in view of the description below, the appended claims, and from the drawings, which are intended to illustrate and not to limit the invention, and wherein:

FIG. 1 is a circuit wiring diagram of a one-transistor DRAM cell known in the prior art.

FIG. 2 is a schematic side view of a one-transistor DRAM cell constructed according to the circuit wiring diagram of FIG. 1.

FIG. 3 is a schematic top view of a one-transistor DRAM cell constructed according to the circuit wiring diagram of FIG. 1.

FIGS. 4-12 are schematic cross-sections illustrating an exemplary process of making an encapsulated electrode line made according to an embodiment of the present invention.

FIG. 13 is a schematic cross-section of a one-transistor DRAM cell made according to an embodiment of the present invention.

FIG. 14 is a schematic cross-section of a DRAM cell having a stacked capacitor, constructed according to an embodiment.

FIGS. 15-22 are schematic cross-sections illustrating an embodiment using the reduction chemistries described above in a gate electrode application.

FIGS. 23-25 are schematic cross-sections illustrating an exemplary metallization process according to an embodiment.

### DETAILED DESCRIPTION OF THE PREFERRED EMBODIMENT

The following detailed description of the preferred embodiments presents a description of certain specific embodiments to assist in understanding the claims. However, one may practice the present invention in a multitude of different embodiments as defined and covered by the claims. Though described in the context of certain preferred materials, it will be understood, in view of the present disclosure, that the methods and structures described herein will have application to a variety of other materials. Furthermore, while described in the context of metallization schemes and gate electrode applications, the skilled artisan will appreciate that the principles and advantages of the processes described herein have application to a variety of process flows.

Definitions

As used herein, the terms “reduction” and “reducing” refer to the removal of oxygen atoms from a metal oxide layer, leaving metal or metallic layers with reduced oxygenation. “Reduction” does not have to be complete reduction, and some oxygen atoms may remain in a metal layer after it has been reduced. Thus, a copper layer that is “at least partially reduced” is a copper layer from which some, but not necessarily all oxygen atoms have been removed. Reduction will be understood to refer to chemical reduction and is to be contrasted with etching.

The term “copper layer” broadly refers to a layer of copper, a layer of copper oxide or a layer that comprises both copper and copper oxide.

The present invention will now be described in connection with preferred embodiments with reference to the accompanying drawings.

Metal Electrode Application

The ALD deposition of copper oxide and easy etching and cleaning properties of copper oxide enables its application as metal electrodes in, for example, capacitors. A metal oxide (e.g., copper oxide) is deposited first as a lower electrode. After patterning, etching and cleaning steps in a preferred embodiment, the copper oxide is reduced to copper metal by means of alcohol, H₂ plasma, etc. A diffusion barrier layer (e.g., TiN, WNC) is deposited prior to dielectric deposition. The final capacitor structure is completed with patterning and etching of the barrier/dielectric layer. However, high temperature treatment is preferably avoided. Those skilled in the art will appreciate that after the metal oxide is reduced, the substrate can be used to form a basic dynamic random access memory (DRAM) cell, as will be more fully described below.

Capacitor structures typically consist of two electrically conductive electrodes and a high-k layer between the electrodes. As the skilled artisan will appreciate, one of the electrodes can be a cell plate to simplify the capacitor connections. The electrodes preferably consist of metals to minimize power losses due to electrical resistance. The addressing lines connected to the memory cells and local capacitor electrodes are preferably encapsulated within diffusion barrier layers to enable the use of highly conductive metals, such as, for example, copper and silver. Stacked capacitors and trench capacitors are generally favored nowadays because capacitors occupy minimum substrate surface area (or “real estate”) for storing a sufficiently large charge. Available substrate area is rather limited because of decreasing feature sizes.

An embodiment of the present invention will be described with reference to a basic DRAM cell that comprises two electrically conductive electrodes and a high-k (high permitivity) layer between the electrodes. A typical process for producing a basic DRAM cell comprises a number of steps, which are illustrated in FIGS. 4 through 13.

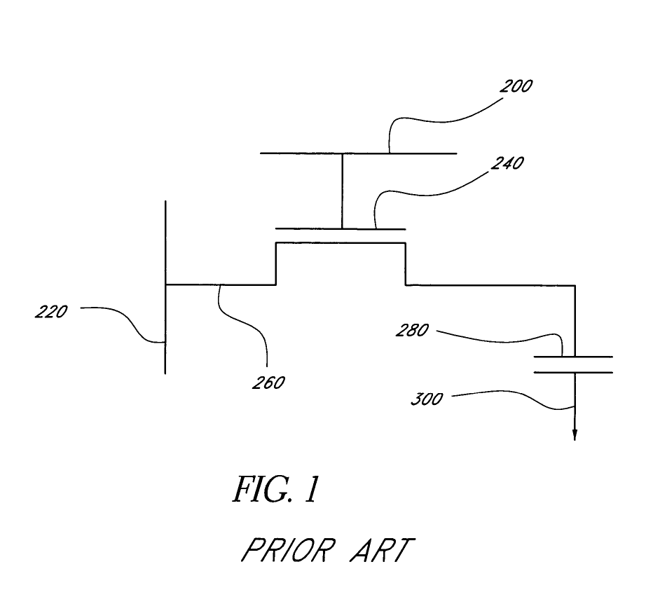

FIG. 1 shows a well known circuit wiring diagram of a one-transistor DRAM cell. A wordline (row) 200 is connected to the gate of a transistor 240. A bitline (column) 220 is connected through a contact plug 260 to the source or drain of the transistor 240. The wordline side of the transistor 240 is not in direct electrical communication with the storage capacitor 280. The drain or source of the transistor 240 is connected in series with a storage capacitor 280 and the storage capacitor 280 includes a reference cell plate 300, which can be common to an entire array of memory cells.

Data is written to the storage capacitor 280 by switching on the transistor 240 with the wordline 200 and writing a high or low voltage level onto the storage capacitor 280 via the bitline 220. Data is stored in the storage capacitor 280 by switching off the transistor 240 by lowering the voltage of the wordline 200 and trapping the voltage/charge on the storage capacitor 280.

Data is read from the storage capacitor 280 by precharging the bitline 220 voltage between the high and low voltage levels, switching on the transistor 240 with the wordline 200 and sensing the bitline voltage change caused by charge sharing between the storage capacitor 280 and the parasitic capacitance of the bitline 220. Decrease of the bitline voltage corresponds to bit 0 (zero) and increase of the bitline voltage corresponds to bit 1 (one).

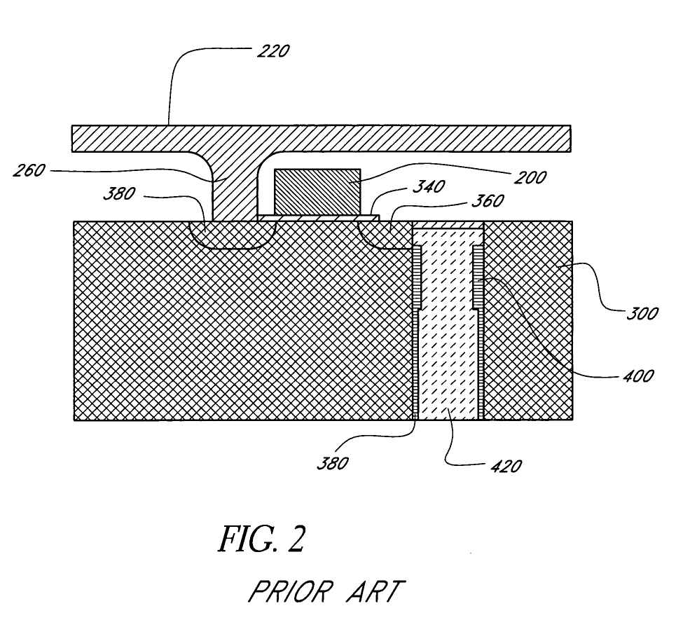

FIG. 2 shows a schematic side view of a one-transistor DRAM cell constructed according to the circuit wiring diagram of FIG. 1. A storage capacitor is constructed in a trench in a substrate 300. The substrate 300 is typically a silicon wafer with p- and n-doped regions. The trench capacitor typically consists of a node dielectric 380, an isolation collar 400, and a polysilicon fill 420. The polysilicon fill 420 of the trench capacitor is in electrical communication with a drain 360 of a transistor. The wordline 200 is deposited on a gate insulator 340. The gate insulator 340 typically comprises silicon dioxide SiO₂, silicon nitride Si₃N₄, or a high-k material, such as hafnium silicate HfSiO₄. The source 380 of the transistor is in electrical communication with the bitline 220 through a contact plug 260. The contact plug 260 may be made of, for example, polysilicon or tungsten metal.

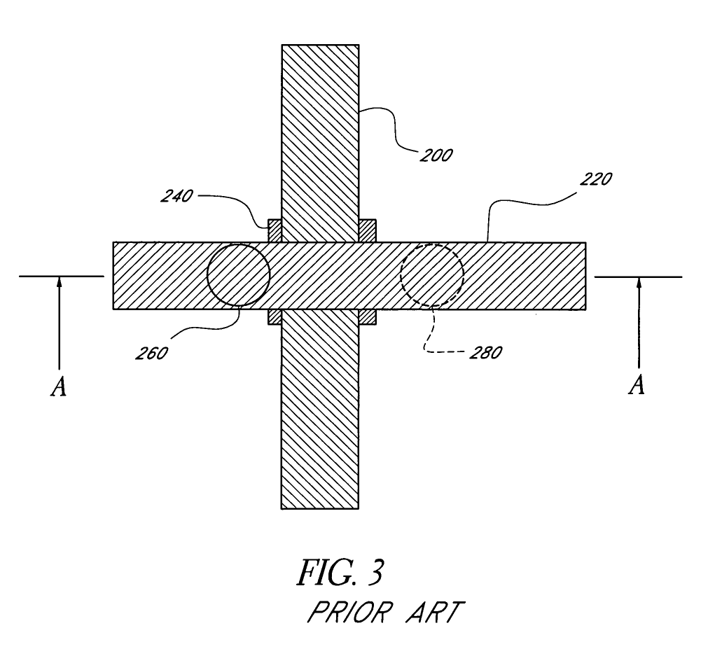

FIG. 3 shows a schematic top view of a one-transistor DRAM cell constructed according to the circuit wiring diagram of FIG. 1. The schematic side view of FIG. 2 is constructed along the cross section “A” of FIG. 3. As shown in FIG. 3, the bitline 220 contact to a transistor is made via a contact plug 260. The approximate gate dielectric area of the transistor is indicated with a square 240. Because of the limited available surface area, the bitline 220 is often located over the storage capacitor 280.

FIGS. 4 through 12 illustrate an exemplary process of making an encapsulated metal element or electrode made according to an embodiment of the present invention. The encapsulated metal element may be used, for example, as wordlines and bitlines in random access memory (RAM) applications, as interconnect lines for other applications, as gate electrodes for PMOS and NMOS logic transistors, or as capacitor plates or electrodes.

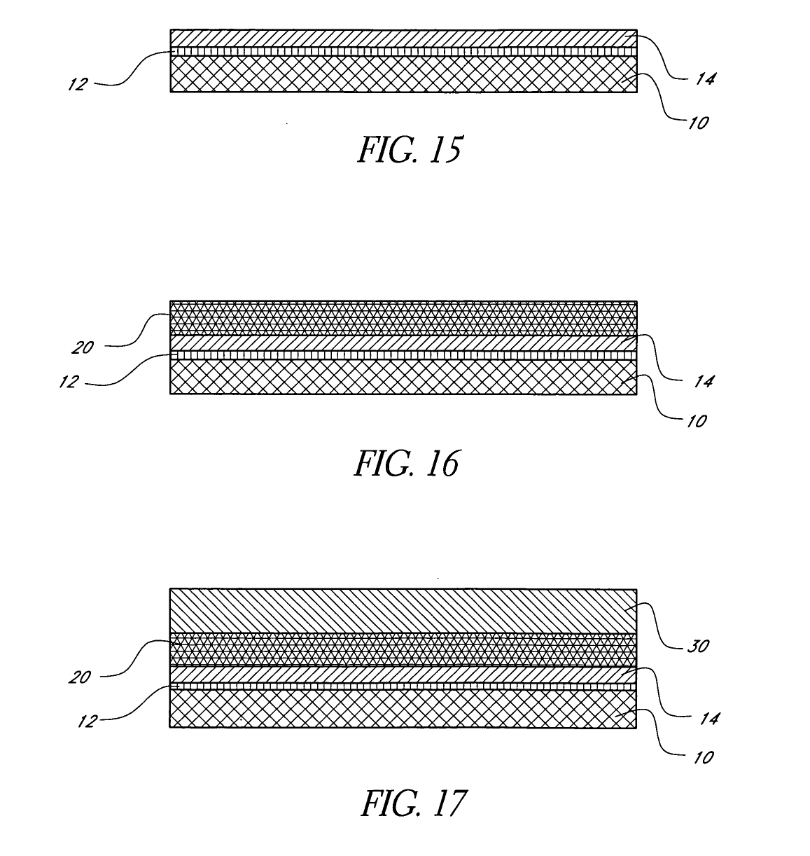

As shown in FIG. 4, an insulator 42 is formed on a substrate 40. The substrate 40 is preferably a silicon wafer. The insulator of a transistor embodiment (see FIGS. 15-22 and attendant text) is thermal oxide formed from the elemental silicon surface by oxidation, and is of a thickness suitable for use as a transistor gate dielectric. The insulating layer 42 in the transistor gate embodiment is preferably formed to a thickness in a range of about 0.5 nm to 5 nm, and more preferably about 1 nm to 3 nm. Alternatively, the insulator 42 layer may be deposited by CVD or ALD. The skilled artisan will readily appreciate that the insulator 42 may comprise any of a number of suitable dielectric materials. Materials suitable for the insulator 42 serving as a gate dielectric include, but are not limited to, silicon dioxide (SiO₂), silicon nitride (Si₃N₄), silicon oxynitride (SiOₓN_{y}), silicates and other high k materials.

The skilled artisan will appreciate that the conductor formation process of FIGS. 4-12 is equally applicable to forming conductors over thick interlevel dielectrics (ILDs), which will be described in more detail below with reference to FIGS. 15-22. In forming conductors over thick ILDs, the insulator 42 is preferably formed to a thickness in a range of about 0.3 μm to 2 μm, and more preferably about 0.5 μm to 1.0 μm. Generally, silicon oxide based materials are preferred insulator materials for thick interlevel insulators (e.g., TEOS, BPSG, etc.) because they can minimize the parasitic capacitance of the electrode line. These low-k dielectric materials include, but are not limited to, polymeric materials, porous oxide materials, and carbon- and fluorine-doped oxides.

A first diffusion barrier 44 is then preferably deposited on the surface of the insulator 42, although this layer can be omitted when the metal to be formed thereover is not fast diffusing or when the underlying insulator 42 serves adequately as a barrier. The diffusion barrier is a material that is inserted between two substances in order to prevent the substances from mixing with each other due to diffusion. In a semiconductor device fabrication process, the diffusion barrier is used not only to prevent the diffusion between a substrate and interconnection material but also to block the interconnection material from diffusing into a dielectric film. The first diffusion barrier 44 is preferably comprised of a conductive diffusion barrier material that contributes to electrical conductivity. Materials suitable for the first diffusion barrier 44 include, but are not limited to, transition metals (e.g., tantalum (Ta)), transition metal nitrides (e.g., titanium nitride (TiN), tantalum nitride (TaN or Ta₃N₅), or tungsten nitride (WN)), transition metal carbides (e.g., tungsten carbide (WC)), and transition metal nitride carbides (e.g., tungsten nitride carbide (WNₓC_{y}) and molybdenum nitride carbide (MoNₓC_{y})). The diffusion barrier 44 is particularly preferred when copper or other fast-diffusing metals are to be formed thereover.

In a preferred embodiment, the diffusion barrier 44 is deposited by ALD. The skilled artisan will appreciate that the diffusion barrier 44 may be deposited by other methods, including but not limited to CVD, PVD, electrochemical deposition (ECD), and sputtering. The diffusion barrier 44 is formed to a thickness adequate for its barrier function. In some arrangements, thickness will depend on other functions, such as defining the work function of a transistor gate stack (see FIGS. 15-22).

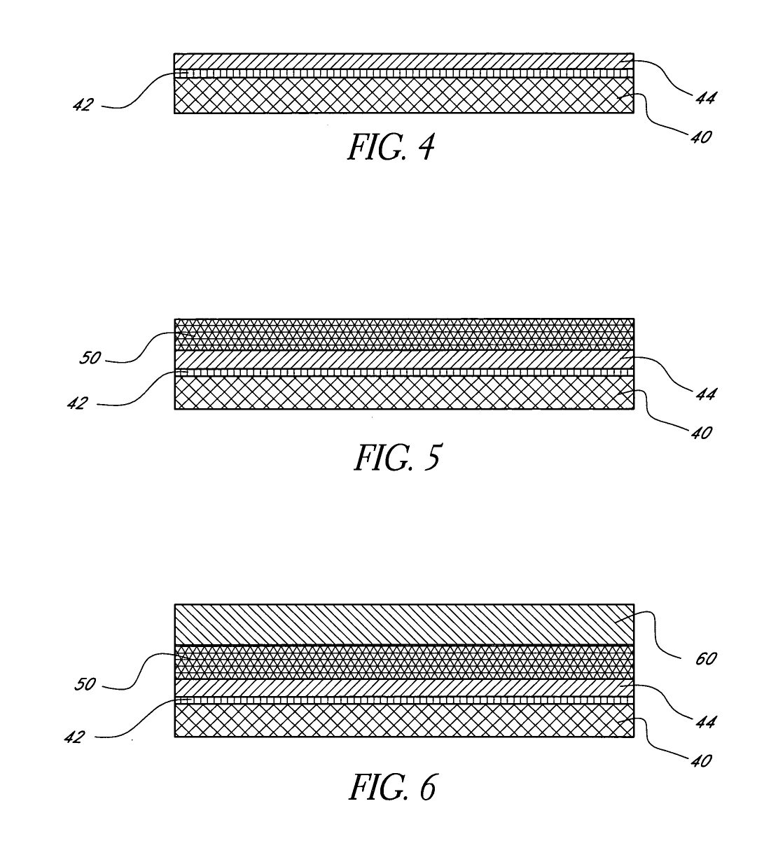

As shown in FIG. 5, a metal oxide film 50 is then deposited on the first diffusion barrier film 44, preferably by ALD, which provides good uniform thickness and high quality of the metal oxide film 50. Depending upon application, the thickness of the metal oxide film 50 is preferably selected from a range of about 0.5 nm-200 nm, and more preferably greater than 1 nm and in exemplary processes from a range of about 10 nm-100 nm. Materials suitable for the metal oxide film 50 include, but are not limited to, copper oxides (CuO, Cu₂O), silver oxide (Ag₂O), and nickel oxide (NiO). The skilled artisan will appreciate that the metal oxide layer may comprise other metal oxides, including but not limited to, oxides of other conductive metals, such as aluminum and ruthenium.

Generally, metal oxides that can be reduced thermally with inorganic compounds (e.g., thermal hydrogen (H₂), hydrogen plasma (H*)), or with organic compounds (e.g., alcohols such as ethanol (C₂H₅OH), aldehydes such as formaldehyde (HCHO), or carboxylic acids such as formic acid (HCOOH)) into elemental metal, are suitable for the metal oxide film 50, as described in U.S. Pat. Nos. 6,482,740 and 6,679,951, U.S. application Ser. Nos. 09/975,466, 10/276,663, and 10/300,169, which are incorporated by reference herein. U.S. Provisional Application No. 60/492,486, which incorporated by reference herein, describes reduction with hydrogen, hydrogen radicals, and carbon monoxide. In certain embodiments, metal oxide thin film is reduced by exposing it to an electric current, as described in U.S. application Ser. No. 10/394,430, which is incorporated by reference.

ALD enables deposition of copper oxide thin film in a complicated integrated circuit structure and provides uniform thickness of the copper oxide film. ALD comprises contacting the substrate with alternating vapor phase pulses of at least two source chemicals. The first source chemical comprises a compound capable of adsorbing, largely intact, no more than a monolayer of metal species on the active sites of a substrate. This adsorption process is self-terminating or saturative. For example, the first source chemical can include ligands that remain on the adsorbed species, which prevents further adsorption. The skilled artisan will appreciate that the first source chemical may be, for example, Cu(thd)₂, Cucl, anhydrous metal nitrate, Co(thd)₃, Pd(thd)₃, or bis(ethylcyclopentadienyl)ruthenium ((EtCp)₂Ru).

Accordingly, deposition temperatures preferably are maintained above the source chemical condensation temperatures and below the source chemical thermal decomposition temperatures. This initial step of adsorption is typically followed by a first removal (e.g., purging) stage, in which the excess first source chemical and possible reaction byproducts are removed from the reaction chamber.

The second source chemical is then introduced into the reaction chamber. The first and second precursors typically tend to react with each other. The second source chemical preferably is a compound capable of oxidizing the metal species on the substrate into the metal oxide, such as, for example, ozone, oxygen, a mixture of ozone and oxygen, vaporized aqueous solution of NH₃, or a mixture of oxygen and water gases.

The adsorbed monolayer of the first source chemical typically reacts instantly with the introduced second source chemical, thereby producing a monolayer or less of the desired thin film on the substrate. This reaction terminates once the adsorbed first source chemical has been consumed. The excess of the second source chemical and possible reaction byproducts are then removed, e.g., by a second purge stage. This cycle can be repeated to grow the film to be a desired thickness. As understood by the skilled artisan, the ALD cycles can also be more complex. For example, the cycles can include three or more reactant pulses separated by purge and/or evacuation steps.

Those skilled in the art will appreciate that copper oxide is easier to etch and pattern than copper metal. With copper oxide etching, copper metal line formation can be directly achieved by selective growth of copper on a pre-patterned copper seed layer without use of the damascene process, where the seed layer is deposited and etched as a metal oxide and subsequently reduced to a more conductive form. The growth of a copper oxide thin film is done by ALD in a preferred embodiment. After the ALD process, the thin film consists essentially of a metal oxide or a mixture of metal oxides, which are then at least partially converted into a metal in a separate process step to increase the conductivity of the copper thin film. The conversion step can be done with any reducing agent, typically in gaseous phase, capable of forming a stronger bond to oxygen than the metal to be reduced, or by application of a suitable current to cause electrolytic reduction.

The metal oxide layer 50 is then coated with a mask layer 60, as shown in FIG. 6. The mask layer 60 is preferably spun on resist, using conventional spin coating equipment. The mask layer 60 is then patterned and etched (e.g., developed photoresist), as shown in FIG. 7, according to conventional photolithography techniques. Alternatively, micromasking and hard mask techniques can be used to define the mask.

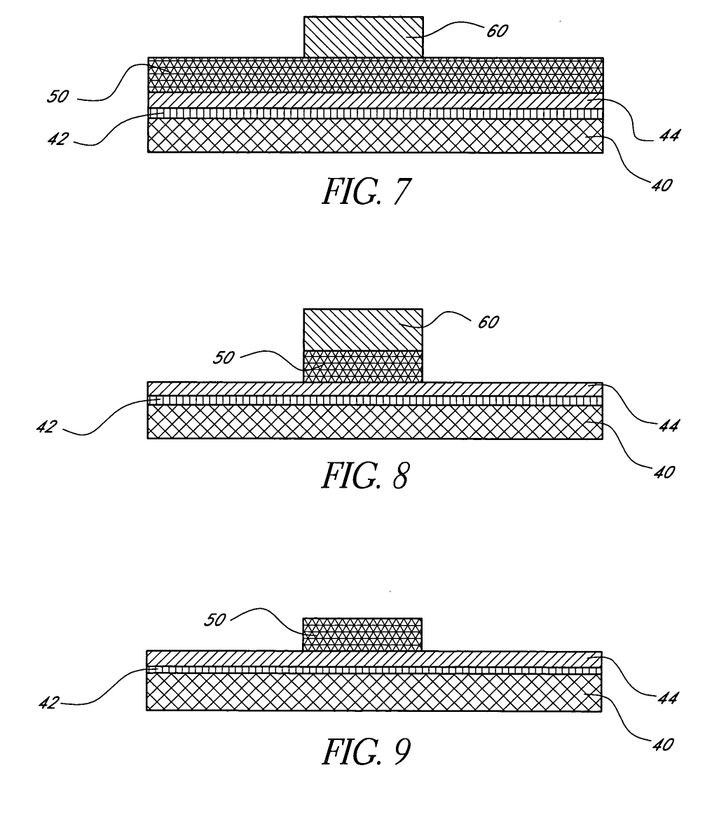

With reference to FIG. 8, the metal oxide 50 is then etched away, using the patterned mask layer 60, from areas that are not needed for an elemental metal conductor. As is known in the art, mask patterns can be transferred by dry or wet etching. In a preferred embodiment, the etching is dry etching, more preferably by anisotropic or directional dry etch.

In dry etching, the etching is accomplished by a reactive gas. Dry etching techniques, include, but are not limited to, plasma etch, reactive ion etch, magnetically enhanced reactive ion etch, inductively coupled plasma, and electron spin resonance. U.S. Pat. No. 5,731,634, which is incorporated by reference, describes various etching techniques. The dry etching is done so that the patterned metal oxide 50 is formed under the patterned resist layer 60. As noted, those skilled in the art will recognize that etching can also be done by wet phase methods, using chemical solutions, such as an acid of a certain concentration. Dry etching allows anisotropic etching, which provides better vertical walls and better fidelity to mask dimensions than wet etching.

As shown in FIG. 9, the remaining mask material 60 on the substrate is removed from the surface of the patterned metal oxide 50 so that the remaining metal oxide 50 is exposed to the surrounding gas atmosphere. Photoresist, for example, is preferably removed by ashing.

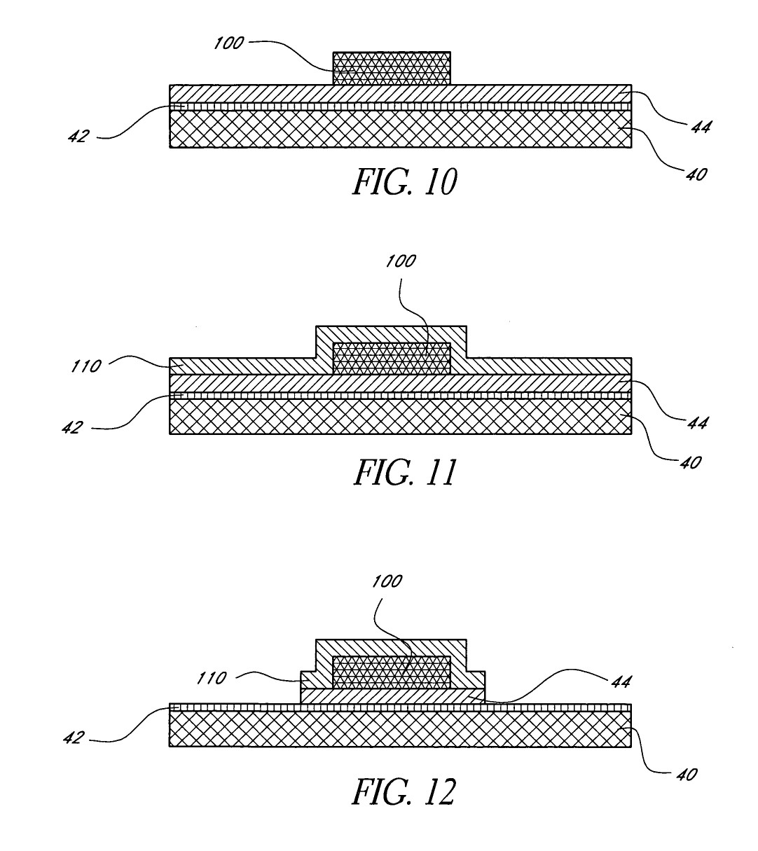

In FIG. 10, the patterned metal oxide 50 (e.g. metal oxide lines) is reduced to form elemental metal 100 in the same pattern. For example, in a preferred embodiment, metal oxide is reduced with hydrogen plasma into a more conductive oxide or elemental metal, which serves as a conductor in the substrate. In a preferred embodiment, copper oxide is reduced to form copper metal.

If the deposition and reduction temperatures are very low, thus causing a slow reduction reaction or slow diffusion of oxygen through the metal oxide layer, the deposition of the metal film can be divided into at least two parts to speed up the total processing time. One layer of the metal oxide, preferably comprising more than one monolayer, is deposited by ALD, then reduced into a metal layer, another layer, preferably comprising more than one monolayer of the metal oxide, is deposited by ALD, then reduced into a metal layer until a metal film of desired thickness is obtained.

In an embodiment, the reduction process uses reducing agents, such as thermal hydrogen, hydrogen radicals, carbon monoxide, or organic compounds that contain at least one functional group selected from the group consisting of alcohols (—OH), aldehydes (—CHO), and carboxylic acids (—COOH). Good adhesion of the reduced metal oxide is preserved when the above-mentioned organic reducing agents are used. Larger reducing agents are particularly preferred to avoid diffusion through the underlying metal. Metal oxide reduction is preferably carried out in a reaction chamber.

In a preferred embodiment of the invention, a copper oxide (CuO) layer is reduced by exposure to an organic reducing agent that is capable of removing oxygen from the copper oxide, leaving elemental copper on the substrate. Preferably, the copper oxide layer is reduced by exposure to an organic reducing agent in vapor form. In a preferred embodiment, the substrate containing the copper oxide layer to be reduced is placed in a reaction space, and the reaction space is evacuated to vacuum. The organic reducing agent is vaporized and fed to the reaction space, optionally with the aid of an inert carrier gas, such as nitrogen. In one embodiment, a vapor mixture is used, comprising two or more reducing agents.

The reducing agent vapor is contacted with the substrate, preferably at low pressure, whereby the copper oxide layer is reduced to copper metal and the reducing agent is oxidized. Typically, the reaction space is then purged with an inert carrier gas to remove the unreacted organic reducing agent and the reaction products and/or by-products.

Theoretically, the reactions between oxide(s) and the reducing agents used in the process of certain embodiments are favorable in a wide temperature range, even as low as room temperature. Preferably, reduction with an organic reducing agent is carried out at low temperatures. Kinetic factors and the diffusion rate of oxygen from copper to the copper surface set a lower limit to the actual process temperatures that can be applied successfully. In this embodiment, the temperature in the reaction space is preferably less than about 450° C., more preferably in the range of about 200° C. to 400° C., and even more preferably about between 300° C. and 400° C. In the case of very thin metal oxide films, the reduction temperature can be even lower than 250° C.

The processing time for metal oxide reduction will vary according to the thickness of the layer to be reduced, as well as the size and reducing strength of the reducing agent. Typically, reduction of a thicker metal oxide layer will take longer than a thinner layer. For example, a layer of copper oxide having a thickness of up to 300 nm to 400 nm can be reduced in approximately 3 to 5 minutes. For layers having a thickness of approximately 0.1 to 10 nm, the processing time is in the order of seconds.

According to an embodiment, reducing agents that comprise relatively bulky organic molecules (alcohols, aldehydes and carboxylic acids) are used. As noted above, bulky source chemical molecules do not easily diffuse inside the metal oxide film. Thus, the reduction reaction takes place only at the surface of the metal oxide layer. During the reduction process, oxygen ions diffuse towards the surface where oxygen is depleted by the reducing chemicals. Gaseous by-products are thus not formed inside the film, but only on the surface. The structural integrity of the forming metal film is thereby preserved and the formation of pinholes on the film will be avoided. The reduction process of such embodiments is preferably carried out in a reaction space that enables controlled temperature, pressure and gas flow conditions.

In certain embodiments, the reduction can be performed by introducing the reducing agent into a tool that may be used for subsequent deposition. For example, the chemical reducing agent can be used in solution in a plating tool, especially in electroless plating tools. Furthermore, reducing can be obtained by applying current, particularly in an ECD tool. In the case of electrochemical reduction, the reduction temperature is preferably between about 0° C. and about 100° C., more preferably between about 20° C. and about 80° C., and most preferably between about 50° C. and about 60° C. The pressure in the reaction space is preferably between 0.01 and 20 mbar, and more preferably between 1 and 10 mbar.

In certain other embodiments, the reducing agent is in gaseous form, as described above. The gaseous reducing agent is capable of taking away the oxygen that is bound to the metal oxide and thus leaves an elemental metal on the substrate surface. For example, primary alcohols react into aldehydes and a water molecule is released as a byproduct. Aldehydes take one oxygen atom and react into carboxylic acids, without the formation of a water molecule.

Organic Reducing Agents

According to a preferred embodiment, copper oxide is reduced to copper metal with one or more organic reducing agents. The organic reducing agents preferably have at least one functional group selected from the group consisting of alcohol (—OH), aldehyde (—CHO), and carboxylic acid (—COOH).

The organic reducing agent is preferably vaporized and fed to the reaction space, optionally with the aid of an inert gas, such as nitrogen. The need for sufficient vapor pressure, sufficient thermal stability at the process temperature and sufficient reactivity are preferably considered in selecting the particular reducing agent(s) to be used. Sufficient vapor pressure means that there should be enough source chemical molecules in the gas phase near the substrate to enable reduction reactions. Sufficient thermal stability means, in practice, that the reducing agent itself should not form growth-disturbing condensable phases on the substrate or leave harmful levels of impurities on the substrate through thermal decomposition. Further selection criteria include, but are not limited to, the availability of the chemical at high purity and the ease of handling.

The reducing agent is contacted with the substrate, whereby the metal oxide layer is reduced, at least partly, and the reducing agent is oxidized. Typically, the reaction space is then purged with an inert carrier gas to remove the unreacted organic reducing agent and reaction products.

The reducing agents are also preferably selected such that the reaction by-products are volatile and can be easily removed from the reaction space. Typically, in the reduction of copper oxide, the reducing agent is also oxidized. Thus, alcohols are oxidized into aldehydes and ketones. Aldehydes are oxidized into carboxylic acids and carboxylic acids are then oxidized into carbon dioxide. Depending on the specific reactants, water may be formed as a gaseous by-product.

Reducing agents containing at least one alcohol group are preferably selected from the group consisting of primary alcohols, secondary alcohols, tertiary alcohols, polyhydroxy alcohols, cyclic alcohols, aromatic alcohols, halogenated alcohols, and other derivatives of alcohols.

Preferred primary alcohols have an —OH group attached to a carbon atom that is bonded to another carbon atom, in particular primary alcohols according to the general formula (I):
R¹—OH (I)
wherein R¹ is a linear or branched C₁-C₂₀ alkyl or alkenyl groups, preferably methyl, ethyl, propyl, butyl, pentyl or hexyl. Examples of preferred primary alcohols include methanol, ethanol, propanol, butanol, 2-methyl propanol and 2-methyl butanol.

Preferred secondary alcohols have an —OH group attached to a carbon atom that is bonded to two other carbon atoms. In particular, preferred secondary alcohols have the general formula (II): 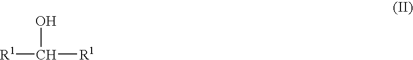
wherein each R¹ is selected independently from the group of linear or branched C₁-C₂₋₀ alkyl and alkenyl groups, preferably methyl, ethyl, propyl, butyl, pentyl or hexyl. Examples of preferred secondary alcohols include 2-propanol and 2-butanol.

Preferred tertiary alcohols have an —OH group attached to a carbon atom that is bonded to three other carbon atoms. In particular, preferred tertiary alcohols have the general formula (III): 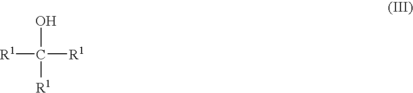
wherein each R¹ is selected independently from the group of linear or branched C₁-C₂₀ alkyl and alkenyl groups, preferably methyl, ethyl, propyl, butyl, pentyl or hexyl. An example of a preferred tertiary alcohol is tert-butanol.

Preferred polyhydroxy alcohols, such as diols and triols, have primary, secondary and/or tertiary alcohol groups as described above. Examples of preferred polyhydroxy alcohols are ethylene glycol and glycerol.

Preferred cyclic alcohols have an —OH group attached to at least one carbon atom which is part of a ring of 1 to 10, more preferably 5-6 carbon atoms.

Preferred aromatic alcohols have at least one —OH group attached either to a benzene ring or to a carbon atom in a side chain. Examples of preferred aromatic alcohols include benzyl alcohol, o-, p- and m-cresol and resorcinol.

Preferred halogenated alcohols have the general formula (IV):
CHₙX₃₋ₙ—R²—OH (IV)
wherein X is selected from the group consisting of F, Cl, Br and I, n is an integer from 0 to 2 and R² is selected from the group of linear or branched C₁-C₂₀ alkyl and alkenyl groups, preferably methyl, ethyl, propyl, butyl, pentyl or hexyl. More preferably X is selected from the group consisting of F and C¹ and R² is selected from the group consisting of methyl and ethyl. An example of a preferred halogenated alcohol is 2,2,2-trifluoroethanol.

Other preferred derivatives of alcohols include amines, such as methyl ethanolamine.

Preferred reducing agents containing at least one aldehyde group (—CHO) are selected from the group consisting of compounds having the general formula (V), alkanedial compounds having the general formula (VI), halogenated aldehydes and other derivatives of aldehydes.

Thus, in one embodiment preferred reducing agents are aldehydes having the general formula (V):
R³—CHO (V)
wherein R³ is selected from the group consisting of hydrogen and linear or branched C₁-C₂₀ alkyl and alkenyl groups, preferably methyl, ethyl, propyl, butyl, pentyl or hexyl. More preferably, R³ is selected from the group consisting of methyl or ethyl. Examples of preferred compounds according to formula (V) are formaldehyde, acetaldehyde and butyraldehyde.

In another embodiment preferred reducing agents are aldehydes having the general formula (VI):
OHC—R⁴—CHO (VI)
wherein R⁴ is a linear or branched C₁-C₂₀ saturated or unsaturated hydrocarbon. Alternatively, the aldehyde groups may be directly bonded to each other (R⁴ is null).

Preferred reducing agents containing at least one —COOH group are preferably selected from the group consisting of compounds of the general formula (VII), polycarboxylic acids, halogenated carboxylic acids and other derivatives of carboxylic acids.

Thus, in one embodiment preferred reducing agents are carboxylic acids having the general formula (VII):
R⁵—COOH (VII)
wherein R⁵ is hydrogen or linear or branched C₁-C₂₀ alkyl or alkenyl group, preferably methyl, ethyl, propyl, butyl, pentyl or hexyl, more preferably methyl or ethyl. Examples of preferred compounds according to formula (VII) are formic acid and acetic acid, most preferably formic acid (HCOOH).

Inorganic Reduction Chemistries and Methods

While copper oxide reduction prior to etch stop deposition is preferably achieved by contacting the substrate with organic reducing agents, particularly large molecule vapor phase reducing agents, other methods of reduction are contemplated. Generally, metal oxides can be reduced thermally into elemental metal with inorganic compounds, such as, for example, thermal hydrogen (H₂) and hydrogen plasma (H*).

In one embodiment, copper oxide is reduced by treatment with hydrogen plasma prior to deposition of a silicon carbide or silicon oxycarbide etch stop layer. Reduction of copper oxide to copper with hydrogen plasma is described, for example, in U.S. Pat. No. 6,033,584, which is incorporated by reference. Briefly, the substrate comprising the copper oxide is placed in a reaction chamber, such as a PECVD reaction chamber. A gas mixture comprising H₂ is allowed to flow into the chamber and Radio Frequency (RF) power is applied to create a plasma discharge in the H₂ gas. The plasma discharge reduces the copper oxide, leaving elemental copper. Care must be taken not to damage the copper surface or other exposed substrate surfaces.

In a further embodiment, copper oxide is reduced by exposure to H₂ gas at elevated temperature. Briefly, the substrate comprising the copper oxide is placed in a reaction chamber. H₂ gas is allowed to flow into the reaction chamber. The temperature of the reaction chamber is preferably set to between about 400° C. and 600° C., more preferably to about 500° C. According to still another embodiment, carbon monoxide (CO) is used for reducing copper oxide into elemental copper.

In certain embodiments, metal oxide thin film is reduced by exposing it to an electric current. In certain such embodiments, the electric current is generated by placing the substrate in an ECD or electromechanical deposition (ECMD) tool, such as the NuTool 2000™ tool available from ASM NuTool, Inc., Milpitas, Calif., USA. Reduction of the metal oxide film to a metal thin film can create a seed layer for subsequent layer formation using ECD or electroless deposition. In certain embodiments, the reduction can be performed in the same ECD tool as is used for subsequent metal deposition.

Electric current can be used as the reducing agent for the CuO film by using the following reactions:
CuO(s)+H₂O+2e⁻→Cu(s)+2OH⁻
2OH⁻→2OH+2e⁻
2OH→H₂O+½O₂(g).

These reactions can be used to reduce copper oxide in ECD tools, and can also be used to reduce ALD-generated copper oxide film, which is deposited on a conductive barrier film layer. The resultant Cu film can then be used as a seed layer in an ECD tool for subsequent metal layer formation.

In Situ Processing

In one embodiment, the copper oxide reduction is carried out in situ in the same reaction space as subsequent processes, such as the deposition of an overlying barrier layer or extension of the reduced copper seed layer by ECD. The copper oxide reduction module may be dedicated to copper oxide reduction or may also be used for other processes. If the module is used for other processes, the other processes are preferably carried out at temperatures comparable to those used for copper oxide reduction.

In other embodiments, reduction can take place in situ in the metal oxide deposition tool. Reactors used for deposition of thin films by ALD are preferably used in the methods of certain embodiments described herein. The deposition of the metal oxide thin film and the reduction step in embodiments using chemical reduction agents are preferably carried out sequentially in one reactor. The reduction process can also be done in a cluster tool where the substrate arrives from a previous process step, the substrate is treated with the reducing agent, and finally transported to the following process step. In a cluster tool, the reaction space temperature can be kept constant, which improves the throughput when compared to a reactor that is heated to the process temperature before each run.

### EXAMPLE 1

### Reduction of CuO with Methanol Vapor

A silicon substrate having a copper oxide coating on copper metal is loaded into a reaction chamber, such as an Eagle 10™ reactor, commercially available from ASM Japan K.K. of Tokyo, Japan. The reaction chamber is evacuated to vacuum and heated to 360° C. The pressure of the reaction chamber is adjusted to about 5-10 mbar with flowing nitrogen gas.

Methanol vapor is mixed with nitrogen gas, introduced to the reaction chamber and contacted with the substrate.

Excess methanol and reaction by-products are purged from the reaction chamber by flowing nitrogen gas.

### EXAMPLE 2

### Reduction of CuO with Ethanol Vapor

A silicon substrate having a copper oxide coating on copper metal is loaded into a reaction chamber, such as the Eagle 10™ reactor. The reaction chamber is evacuated to vacuum and heated to 360° C. The pressure of the reaction chamber is adjusted to about 5-10 mbar with flowing nitrogen gas.

Ethanol vapor is mixed with nitrogen gas, introduced to the reaction chamber and contacted with the substrate.

Excess ethanol and reaction by-products are purged from the reaction chamber by flowing nitrogen gas.

### EXAMPLE 3

### Reduction of CuO with 2-Propanol Vapor

A silicon substrate having a copper oxide coating on copper metal is loaded into a reaction chamber, such as the Eagle 10™ reactor. The reaction chamber is evacuated to vacuum and heated to 360° C. The pressure of the reaction chamber is adjusted to about 5-10 mbar with flowing nitrogen gas.

2-propanol (also known as isopropanol) vapor is mixed with nitrogen gas, introduced to the reaction chamber and contacted with the substrate.

Excess 2-propanol and reaction by-products are purged from the reaction chamber by flowing nitrogen gas.

### EXAMPLE 4

### Reduction of CuO with Tert-Butanol Vapor

A silicon substrate having a copper oxide coating on copper metal is loaded into a reaction chamber, such as the Eagle 10™ reactor. The reaction chamber is evacuated to vacuum and heated to greater than 385° C. The pressure of the reaction chamber is adjusted to about 5-10 mbar with flowing nitrogen gas.

Tert-butanol vapor is mixed with nitrogen gas, introduced to the reaction chamber and contacted with the substrate.

Excess tert-butanol and reaction by-products are purged from the reaction chamber by flowing nitrogen gas.

### EXAMPLE 5

### Reduction of CuO with Butyraldehyde Vapor

A silicon substrate having a copper oxide coating on copper metal is loaded into a reaction chamber, such as the Eagle 10™ reactor. The reaction chamber is evacuated to vacuum and heated to 360° C. The pressure of the reaction chamber is adjusted to about 5-10 mbar with flowing nitrogen gas.

Butyraldehyde vapor is mixed with nitrogen gas, introduced to the reaction chamber and contacted with the substrate.

Excess butyraldehyde and reaction by-products are purged from the reaction chamber by flowing nitrogen gas.

### EXAMPLE 6

### Reduction of CuO with Formic Acid Vapor

A silicon substrate having a copper oxide coating on copper metal is loaded into a reaction chamber, such as the Eagle 10™ reactor. The reaction chamber is evacuated to vacuum and heated to 310° C. The pressure of the reaction chamber is adjusted to about 5-10 mbar with flowing nitrogen gas.

Formic acid vapor is mixed with nitrogen gas, introduced to the reaction chamber and contacted with the substrate.

Excess formic acid and reaction by-products are purged from the reaction chamber by flowing nitrogen gas.

### EXAMPLE 7

### Reduction of CuO with Acetic Acid Vapor

A silicon substrate having a copper oxide coating on copper metal is loaded into a reaction chamber, such as the Eagle 0™ reactor. The reaction chamber is evacuated to vacuum and heated to 360° C. The pressure of the reaction chamber is adjusted to about 5-10 mbar with flowing nitrogen gas.

Acetic acid vapor is mixed with nitrogen gas, introduced to the reaction chamber and contacted with the substrate.

Excess acetic acid and reaction by-products are purged from the reaction chamber by flowing nitrogen gas.

### EXAMPLE 8

### Reduction of CuO with Plasma

A silicon substrate having a copper oxide coating on copper metal is loaded into a reaction chamber, such as the Eagle 10™ reactor. The reaction chamber is evacuated to vacuum and heated to approximately 300° C. The pressure of the reaction chamber is adjusted to about 5-10 mbar with flowing gas comprising hydrogen.

A plasma discharge or glow is created in the hydrogen gas by the application of RF power. Plasma treatment is continued for approximately 2 minutes.

Reaction byproducts are purged from the reaction chamber with flowing nitrogen gas.

### EXAMPLE 9

### Reduction of CuO with Hydrogen

A silicon substrate having a copper oxide coating on copper metal is loaded into a reaction chamber, such as the Eagle 10™ reactor. The reaction chamber is evacuated to vacuum, heated to approximately 500° C. and the pressure of the reaction chamber is adjusted to about 5-10 mbar with flowing nitrogen gas.

Hydrogen gas is mixed with nitrogen gas (10% hydrogen by volume), introduced to the reaction chamber and contacted with the substrate. Reaction byproducts are purged from the reaction chamber with flowing nitrogen gas.

In an embodiment, an electrochemical deposition (ECD) process is applied after reduction of copper oxide. As understood by the skilled artisan, all metal wiring needs to be interconnected for the ECD process. Selective growth of copper metal on the copper seed layer can be achieved for microelectronic applications. Other alternatives for copper electroplating include electroless plating and selective CVD.

In an electroplating process, a substrate having a conductive seed layer is immersed in a metal compound solution. The electrically conductive surface of the substrate is connected to an external DC power supply. A current passes through the substrate surface into the solution and metal is deposited on the substrate. As understood by the skilled artisan, a uniform and continuous seed layer is necessary for uniform electroplated metal (e.g., copper). The skilled artisan will appreciate that the electroplating process could be in situ with electrolytic or electrochemical reduction of the metal oxide to metal.

As shown in FIG. 11, after reduction of the metal oxide to elemental metal and any subsequent selective growth (e.g., ECD) on the reduced layer, a second diffusion barrier film 110 is then preferably deposited conformally onto the substrate so that the first diffusion barrier film 44 and the metal lines 100 are covered, and the metal lines 100 are surrounded by the first and second diffusion barrier films 44, 110. The thickness of the second diffusion barrier film 110 is preferably selected from a range of about 1 nm-50 nm, and more preferably from a range of about 5 nm to 20 nm. In a preferred embodiment, the second diffusion barrier film 110 may be formed from the same material as the first diffusion barrier film 44 for simplifying the process. Alternatively, the second diffusion barrier film 110 may be formed from a different material because the second diffusion barrier film 110 does not affect the work function of the transistor gate.

With reference to FIG. 12, the substrate is then coated with a mask material (not shown) that is patterned. The first diffusion barrier 44 and the second diffusion barrier 110 are then etched through the mask, which is preferably wider than the mask 60 of FIGS. 7-9, so that the metal lines 100 remain encapsulated within the diffusion barrier films 44, 110. Any residual mask material is then removed from the surface of the second diffusion barrier 110.

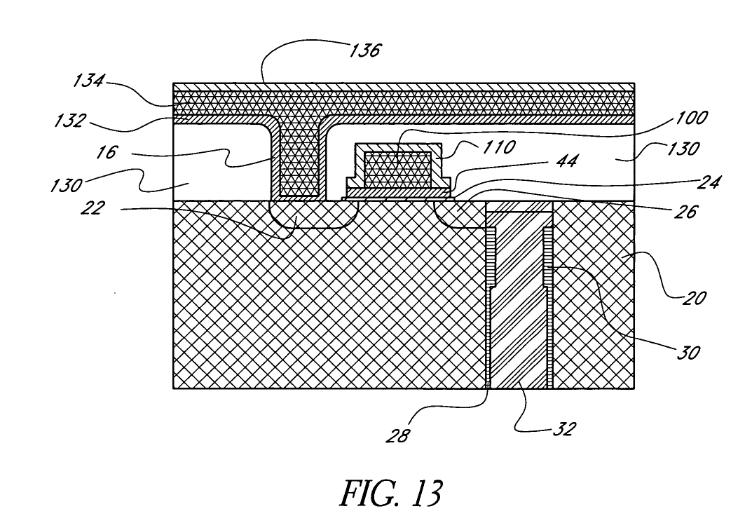

FIG. 13 is a schematic side view of a one-transistor DRAM cell made according to an embodiment of the present invention. The skilled artisan will recognize that some doping profiles in the substrate 20 are omitted from FIG. 13 in order to simplify the schematic. FIG. 13 shows a silicon substrate having doped source 22 and drain 26 regions and a trench capacitor. The trench capacitor consists of a node dielectric 28, an isolation collar 30, and a polysilicon fill 32.

As shown in FIG. 13, a gate insulator 24 (e.g., hafnium dioxide HfO₂) is formed on the substrate by depositing a film, preferably by ALD. The skilled artisan will recognize that other deposition techniques may be used to deposit the thin film. The first diffusion barrier 44 (e.g., titanium nitride (TiN)), the metal conductor 100 (e.g., copper (Cu)), and the second diffusion barrier 110 (e.g., titanium nitride (TiN)) are deposited, patterned, and etched, in accordance with an embodiment, as shown in FIGS. 4 through 12 and described above. The conductor 100 of the illustrated embodiment serves as a metal wordline above a transistor gate. Although not shown, the gate stack can also include insulating sidewall spacers and cap layer, as will be appreciated by the skilled artisan. Insulating barrier materials, such as Si₃N₄ can also obviate the second diffusion barrier 110.

An insulating layer 130 (e.g., SiO₂ or low-k material) is then deposited on the substrate and planarized, preferably with chemical mechanical polishing (CMP). The insulating layer 130 is patterned and contact plug vias are then etched into the insulating layer 130. Repeating the process of FIGS. 4-12 now, for interconnect metallization this time, a third diffusion barrier layer 132 (e.g., TiN) is deposited, preferably by ALD, on the substrate so that the conformal film covers all of the surfaces down to the bottom of the contact plug vias. A metal oxide film (not shown) is then deposited on the third diffusion barrier layer 132. The metal oxide film is then patterned and etched so that the metal oxide film remains in the via and bitline areas. The metal oxide film is then reduced into the elemental metal that defines the contact plugs 16 and the bitlines 134. After any selective growth (e.g., by ECD) of the patterned and reduced metal, a fourth diffusion barrier film 136 is then deposited on the substrate and patterned. The third and fourth diffusion barrier films 132, 136 are etched so that the elemental metal in the contact plugs 16 and bitlines 134 remain encapsulated within the diffusion barrier films 132, 136 while other surface areas of the insulating film 130 become exposed to the surrounding atmosphere.

In case a diffusion barrier is conductive, the diffusion barrier contributes to the electrical conductivity of the electrode. Examples of electrically conductive diffusion barriers include titanium nitride (TiN), tantalum nitride (TaN), and tungsten nitride carbide (WNₓC_{y}). In case of insulating diffusion barriers, the diffusion barrier may affect parasitic capacitance of the electrode line. Examples of insulating diffusion barriers are aluminum oxide (Al₂O₃) and silicon nitride (Si₃N₄).

The diffusion barriers are desirable for metals that have high diffusion rate through materials or react with the surrounding insulators. Examples of high diffusion rate metals are copper and silver. Diffusion barriers can be eliminated when the metal to be used as an electrode has low diffusion rate through materials and does not react with the surrounding materials. Ruthenium (Ru) serves as an example of a low diffusion rate metal.

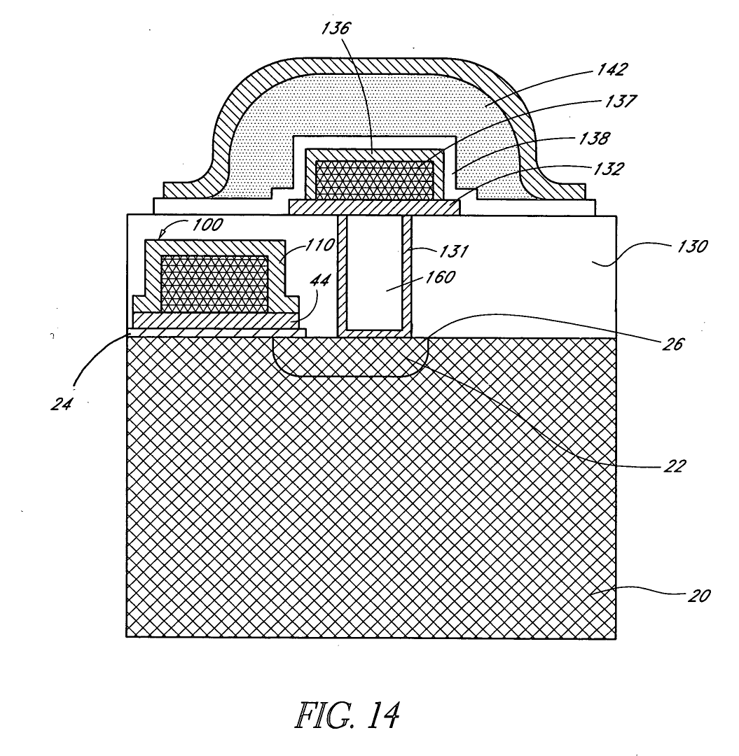

FIG. 14 is a schematic side view of a DRAM cell having a stacked capacitor. The structure of the cell is similar to the DRAM cell shown in FIG. 13 (like parts referenced by like numbers), with a stacked capacitor in place of the trench capacitor. The substrate 20 is typically a silicon wafer with p- and n-doped regions. The gate insulator 24 typically consists of silicon dioxide SiO₂, silicon nitride Si₃N₄, or a high-k material, such as hafnium silicate HfSiO₄. The gate insulator 24 is preferably deposited, and a metal wordline 100 (e.g., copper(Cu)) is deposited on the gate insulator 24, preferably in accordance with the embodiment described with reference to FIG. 13 above.

An insulating layer 130 (e.g., SiO₂ or low-k material) is then deposited in the substrate and planarized, preferably with CMP. The insulating layer is then patterned and vias for conductive plugs 160 are etched into the insulating layer 130. A diffusion barrier layer 131 (e.g., TiN) is preferably first deposited, preferably by ALD, so that the diffusion barrier film covers the entire surface, down to the bottom of the vias. The vias are preferably filled with a polysilicon or tungsten material.

A second diffusion barrier layer 132 is then deposited over the substrate and patterned to cover the plug 160. A metal oxide film (not shown) is then deposited over the second diffusion barrier layer 132. The metal oxide film is then patterned and etched so that it remains over the plug 16. The metal oxide film is then reduced into elemental metal 137 that forms or serves as a seed layer for a capacitor bottom electrode.

A third diffusion barrier layer 136 is then deposited over the surface, as shown in FIG. 14, to encapsulate the metal electrode 137. A capacitor dielectric material 138 is then deposited over the surface. A top or reference electrode 142 is then deposited over the capacitor dielectric material 138,

Gate Electrode Applications—Transistors

The reduction of etchable metal oxide, as described above, can be used also in gate electrode applications. Transistor gate structures typically consist of a gate insulator and a gate electrode on top of the gate insulator. An electrically conductive diffusion barrier may be placed between the gate insulator and a highly conductive metal strapping layer over the diffusion barrier. Additionally, the gate electrode can be encapsulated within a diffusion barrier.

When a minimum thickness of the diffusion barrier is selected (e.g., 100 Å), the material of the diffusion barrier will define the work function for the gate electrode, while the metal formed thereover conducts the majority of current laterally across the substrate. An embodiment using the reduction chemistries described above in a gate electrode application will be described below with reference to FIGS. 15-22.

Due to the good etching and cleaning properties of copper oxide, it can be used during fabrication of a copper gate electrode in a CMOS structure. In a preferred embodiment, a gate dielectric, an electrically conductive diffusion barrier (such as TiN, WNC, etc. that determines work function) and copper oxide are deposited after thermal activation of implanted source and drain areas to avoid exposing the metal to later high temperature steps. The gate dielectric, diffusion barrier, and copper oxide stack can be then patterned and etched. After deposition, the copper oxide can be reduced by means of alcohol, H₂ plasma, etc. to form a gate electrode.

A substrate 10 is provided, preferably a silicon wafer that has an insulating layer 12 deposited on its surface, as shown in FIG. 15. The insulating layer 12 preferably comprises an electrical insulator material, such as, for example, thermal silicon dioxide (SiO₂), deposited SiO₂, silicon nitride (Si₃N₄), hafnium oxide (HfO₂), zirconium oxide (ZrO₂), aluminum oxide (Al₂O₃), or combinations thereof (e.g., nanolaminates, silicates, etc.). The skilled artisan will readily appreciate that the insulating layer 12 may comprise any of a number of suitable dielectric materials. The insulating layer 12 is preferably formed to an “equivalent oxide thickness” (EOT) of about 3 Å to 25 Å, and more preferably about 5 Å to 15 Å.

As shown in FIG. 15, a diffusion barrier layer 14, preferably a conductive diffusion barrier material such as titanium nitride (TiN), tantalum nitride (TaN), or tungsten nitride carbide (WNₓC_{y}), is preferably deposited on the insulating layer 12. The diffusion barrier layer 14 is preferably comprised of a conductive diffusion barrier that contributes to electrical conductivity. In a preferred embodiment, the diffusion barrier layer 14 is deposited by ALD. The skilled artisan will appreciate that the diffusion barrier layer 14 may be deposited by other methods, including but not limited to CVD, PVD, ECD, and sputtering. The diffusion barrier layer 14 is preferably formed to a thickness of about 5 nm to 100 nm, and more preferably about 10 nm to 30 nm. As understood by the skilled artisan, the diffusion barrier layer 14 should be thick enough to define the transistor gate work function.

With reference to FIG. 16, a metal oxide layer 20 is then deposited on the diffusion barrier layer 14. In a preferred embodiment, the metal oxide layer 20 comprises copper oxide (CuO) and is deposited by ALD, preferably blanket deposited over a planar surface. The skilled artisan will appreciate that the metal oxide layer may comprise other metal oxides, including but not limited to, oxides of other conductive film, such as aluminum, silver, and ruthenium.

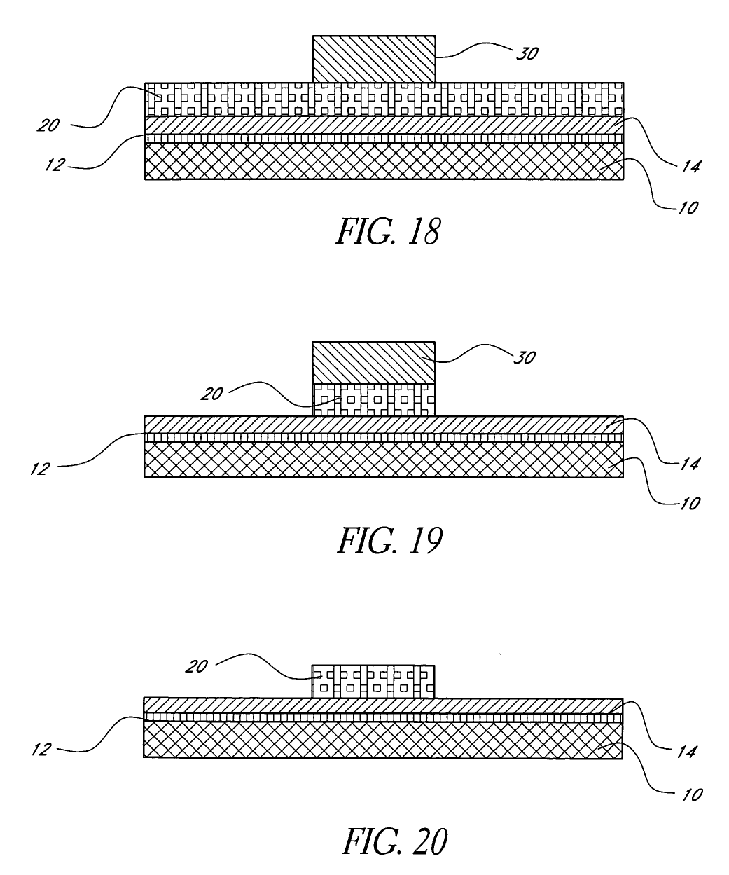

The metal oxide layer 20 is then coated with a layer 30 of masking material, such as a spun-on photoresist, as shown in FIG. 17. The mask layer 30 is then patterned, such as by conventional photolithography techniques, as shown in FIG. 18.

With reference to FIG. 19, the metal oxide layer 20 is then etched away from exposed areas to form a desired wiring pattern. Preferably, the etching is dry etching.

The remaining mask material 30 on the substrate is then removed from the surface of the patterned metal oxide 20 so that the metal oxide 20 is exposed, as shown in FIG. 20. Resist 30, or example, is preferably removed by ashing.

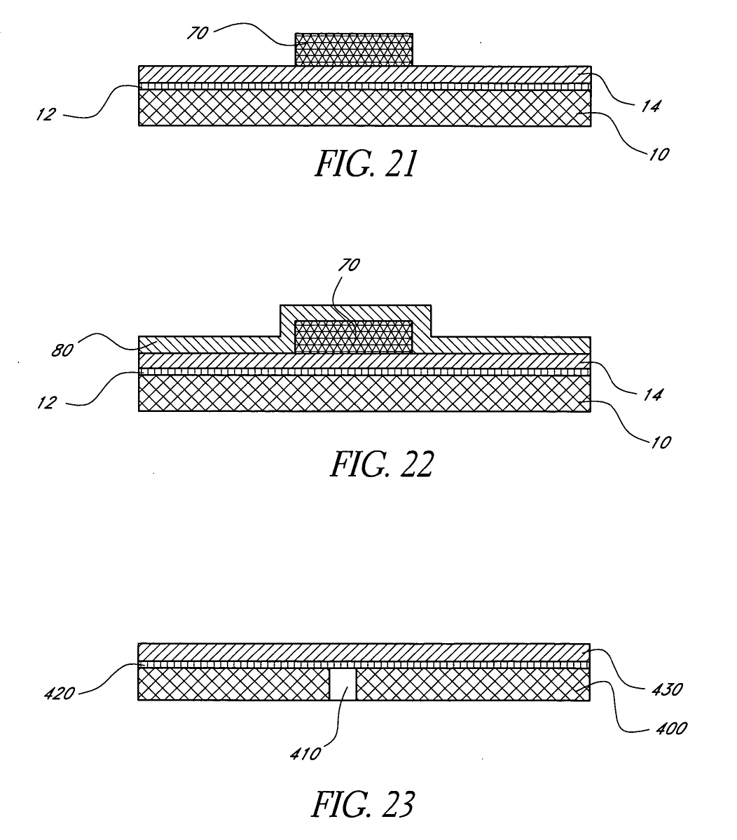

The patterned metal oxide 20 is then reduced to form elemental metal 70, as shown in FIG. 21, in order to form the transistor gate of the semiconductor device. In a preferred embodiment, copper oxide is reduced to form copper metal 70, which serves as a conductor. In a preferred embodiment, the reduction uses reducing agents, such as thermal hydrogen, hydrogen radicals, carbon monoxide, or organic compounds that contain at least one functional group selected from the group consisting of alcohols (—OH), aldehydes (—CHO), and carboxylic acids (—COOH), as described in more detail above. The skilled artisan will appreciate that other reduction chemistries, including those described above, or current may be used to reduce the metal oxide 20 to form elemental metal 70. After reduction to form elemental metal, a diffusion barrier layer 80 is deposited over the surface such that the metal 70 is surrounded by the diffusion barrier layers 14, 80, as shown in FIG. 22. Alternatively, conventional insulating cap layers and sidewall spacers (e.g., Si₃N₄) can be formed to encapsulate the copper 70.

Metallization Application

An exemplary metallization process will described with reference to FIGS. 23-25. A substrate having an insulating layer 400 is provided. The insulating layer 400 preferably comprises an ILD material, such as, for example, silicon dioxide (SiO₂), polyimide, TEOS, BPSG, fluorinated or carbon-doped oxides, etc. A via for a conductive plug is etched in the insulating layer 400. The via is preferably filled with a conductive material, such as metal, to form a plug 410. A conductive barrier layer 420 is then deposited on the substrate. A metal oxide thin film 430 is then deposited, preferably by ALD.

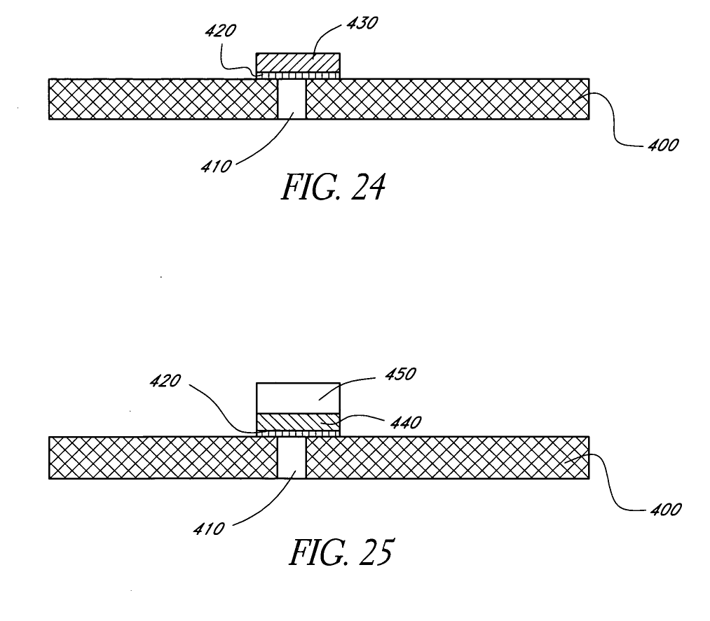

As shown in FIG. 24, the metal oxide 430 and conductive barrier layer 420 are then patterned and etched. The metal oxide 430 is then reduced, using a reduction method as described above, to elemental metal 440 to form a conductive seed layer, as shown in FIG. 25. An electrically conductive seed layer is typically needed for electroplating processes. The electrically conductive seed layer can be used for subsequent layer formation using ECD or electroless deposition.

While not visible from the view of FIGS. 23-25, it will be understood that the pattern includes not only the illustrated line in the plane into and out of the page, but that it is also interconnected with other lines across the substrate in a wiring pattern. Thus, the reduced lines can carry current for ECD across the substrate.

The substrate having an electrically conductive seed layer 440 is typically placed in a bath containing a metal compound solution and connected to an external DC power supply. A current passes through the substrate surface into the solution and bulk metal 450 is deposited on the substrate. The seed layer 440 has high conductivity and it acts as a conduction and nucleation layer for the electroplating process. Alternatively, a seed layer 440 can also act as a nucleation layer also for selective CVD processes. The seed layer 440 carries current from the edge of the wafer to the center of the wafer and from the top surface of the substrate into the bottom of vias and trenches. A uniform and continuous seed layer across the substrate is necessary to form, for example, uniform electroplated copper. As understood by the skilled artisan, the quantity of the deposited metal is directly proportional to the local current density on the substrate.

As will be appreciated by the skilled artisan, metal line formation processes typically employ one metal composition throughout various wiring layers (e.g., copper interconnects or aluminum interconnects. Those skilled in the art may practice the principles of the present invention in other specific forms without departing from its spirit or essential characteristics. Accordingly, the disclosed embodiments of the invention are merely illustrative and do not serve to limit the scope of the invention set forth in the following claims.

Although the foregoing invention has been described in terms of certain preferred embodiments, other embodiments will be apparent to those of ordinary skill in the art. Additionally, other combinations, omissions, substitutions and modification will be apparent to the skilled artisan, in view of the disclosure herein. Accordingly, the present invention is not intended to be limited by the recitation of the preferred embodiments, but is instead to be defined by reference to the appended claims.

We claim:

1. A method of producing a conductive thin film, comprising:
depositing metal oxide on a substrate by atomic layer deposition;
patterning the metal oxide; and
at least partially reducing the metal oxide to a more conductive form after patterning.

2. The method of claim 1, wherein patterning comprises dry etching the metal oxide before reducing.

3. The method of claim 1, wherein atomic layer deposition comprises contacting the substrate with alternating vapor phase pulses of:
at least one first source chemical comprising a compound capable of adsorbing no more than a monolayer of metal species on the substrate; and
at least one second source chemical comprising a compound capable of oxidizing the metal species on the substrate into the metal oxide.

4. The method of claim 3, wherein the first source chemical is Cu(thd)₂ and the second source chemical is selected from the group consisting of ozone, oxygen, and a mixture of ozone and oxygen.

5. The method of claim 3, wherein the first source chemical is CuCl.

6. The method of claim 3, wherein the first source chemical is anhydrous metal nitrate.

7. The method of claim 3, wherein the first source chemical is Co(thd)₃.

8. The method of claim 3, wherein the first source chemical is Pd(thd)₃ and the second source chemical is selected from the group consisting of ozone, oxygen, and a mixture of ozone and oxygen.

9. The method of claim 3, wherein the first source chemical is bis(ethylcyclopentadienyl)ruthenium ((EtCp)₂Ru) and the second source chemical is a mixture of oxygen and water gases.

10. The method of claim 1, wherein at least partially reducing the metal oxide comprises exposure to at least one organic reducing agent that is capable of removing oxygen from the metal oxide.

11. The method of claim 10, wherein the at least one organic reducing agent is in vapor form.

12. The method of claim 10, wherein the at least one organic reducing agent is selected from the group consisting of alcohol, aldehyde, and carboxylic acid.

13. The method of claim 1, wherein at least partially reducing the metal oxide comprises treatment with hydrogen plasma.

14. The method of claim 1, wherein at least partially reducing the metal oxide comprises treatment with thermal hydrogen.

15. The method of claim 1, wherein at least partially reducing the metal oxide comprises applying an electric current.

16. The method of claim 1, wherein the metal oxide is copper oxide.

17. The method of claim 16, wherein the copper oxide has a thickness of at least 1 nm.

18. The method of claim 1, further comprising placing the substrate into a metal compound solution after reducing and connecting the substrate to an external DC power supply.

19. The method of claim 1, further comprising:
depositing a first diffusion barrier layer on the substrate before depositing the metal oxide; and
depositing a second diffusion barrier layer over the substrate after at least partially reducing.

20. The method of claim 19, wherein the first diffusion barrier layer comprises a conductive diffusion barrier material.

21. A method of producing a transistor gate, comprising:
depositing an insulating layer on a substrate;
depositing a first diffusion barrier layer on the insulating layer;
depositing metal oxide on the first diffusion barrier layer by atomic layer deposition;
masking the metal oxide;
dry etching the metal oxide after masking;
at least partially chemically reducing the metal oxide after dry etching; and
depositing a second diffusion barrier layer on the substrate after at least partially chemically reducing the metal oxide.

22. The method of claim 21, wherein the first diffusion barrier layer comprises a conductive material.

23. The method of claim 21, wherein the atomic layer deposition comprises a plurality of cycles, each cycle comprising:
contacting the substrate with a vapor phase pulse of a first source chemical comprising a compound capable of adsorbing no more than a monolayer of metal species on the substrate;
removing any excess first source chemical and byproduct;
contacting the substrate with a second source chemical comprising a compound capable of oxidizing the metal species on the substrate into the metal oxide; and
removing any excess of the second source chemical and byproduct.

24. The method of claim 21, wherein at least partially reducing the metal oxide comprises exposure to at least one organic reducing agent that is capable of removing oxygen from the metal oxide.

25. The method of claim 24, wherein the at least one organic reducing agent is selected from the group consisting of alcohol, aldehyde, and carboxylic acid.

26. The method of claim 24, wherein the at least one organic reducing agent is in vapor form.

27. The method of claim 21, wherein the metal oxide is copper oxide.

28. The method of claim 21, wherein at least partially chemically reducing the metal oxide comprises treatment with hydrogen plasma.

29. The method of claim 21, wherein at least partially chemically reducing the metal oxide comprises treatment with thermal hydrogen.

30. The method of claim 21, wherein at least partially chemically reducing the metal oxide comprises applying an electric current to the metal oxide.

31. A method of forming copper features in an integrated circuit, comprising:
depositing a blanket layer of copper oxide by atomic layer deposition;
masking and dry etching the copper oxide to form a patterned copper oxide thin film; and
reducing the copper oxide to form copper metal.

32. The method of claim 31, wherein atomic layer deposition comprises contacting the substrate with alternating vapor phase pulses of at least one first source chemical comprising a compound capable of adsorbing no more than a monolayer of metal species on the substrate and at least one second source chemical comprising a compound capable of oxidizing the metal species on the substrate into the metal oxide.

33. The method of claim 31, wherein reducing the copper oxide comprises exposure to at least one organic reducing agent.

34. The method of claim 31, wherein reducing the copper oxide comprises exposure to at least one inorganic reducing agent.

35. The method of claim 31, wherein reducing the copper oxide comprises by exposure to an electrical current.

36. The method of claim 31, further comprising selectively depositing copper on the copper metal left by reducing the copper oxide.

37. The method of claim 36, wherein selectively depositing comprises electrochemical deposition.

38. The method of claim 31, further comprising depositing a blanket layer of diffusion barrier material prior to depositing the blanket layer of copper oxide.

39. The method of claim 38, further comprising encapsulating the copper metal with a diffusion barrier material after reducing the copper oxide.

40. The method of claim 31, wherein masking and dry etching comprises defining a pattern of interconnect lines.

41. The method of claim 31, wherein masking and dry etching comprises producing a pattern of a plurality of isolated capacitor electrodes.

42. The method of claim 31, wherein the copper metal is formed over a material layer defining a work function of a transistor gate electrode.

43. A method of forming patterned metal features in an integrated circuit, comprising:
depositing a blanket layer of metal oxide in an atomic layer deposition comprising a plurality of cycles, each cycle including:
saturating a substrate surface with a first chemical precursor containing metal, the first chemical precursor adsorbing no more than about one monolayer across the substrate,
removing excess gas phase first precursor and any by-product from the substrate,
exposing the substrate to a second chemical precursor containing oxygen, the second chemical precursor oxidizing the first chemical precursor adsorbed on the substrate to form no more than about a monolayer of metal oxide, and
removing excess gas phase second chemical precursor and by-product from the substrate;
masking and etching the metal oxide to form a patterned metal oxide; and
chemically or electrically reducing the patterned metal oxide to form a conductive layer.
